(19) United States
(12) Patent Application Publication
(10) Pub. No.: US 2025/0273917 A1
(43) Pub. Date: Aug. 28, 2025

(54) Shielded Connection Interface Adapter with Stacked Laminated Portions

(71) Applicant: PMK Mess- und Kommunikationstechnik, GmbH, Bad Soden am Taunus (DE)

(72) Inventors: Mark Heimann, Bad Soden am Taunus (DE); Jurij Weber, Schwalbach am Taunus (DE)

(21) Appl. No.: 19/063,274

(22) Filed: Feb. 25, 2025

Related U.S. Application Data
(60) Provisional application No. 63/557,593, filed on Feb. 25, 2024.

(51) Int. Cl. H01R 24/54; G01R 1/04; G01R 1/067; H01R 24/22; H01R 24/30

(52) U.S. Cl. CPC H01R 24/542; G01R 1/0416; G01R 1/06772; H01R 24/22; H01R 24/30

(57) ABSTRACT

An adapter for establishing a high-quality planned test point on a device under testing. The adapter has two laminated portions arranged in a stacked configuration that houses a bridge insert, adapting from an input socket to an output socket. Input and output ports are electromagnetically shielded internally and from external electromagnetic interference, ensuring reliable and low-impedance connections.

### CROSS REFERENCE TO RELATED APPLICATION

This application claims the benefit of U.S. provisional application No. 63/557,593 entitled Stacked Adapter having a filing date of Feb. 25, 2024, the entire contents of which are incorporated by reference herein.

### FIELD OF THE DISCLOSURE

The present invention pertains to the field of electronics testing and signal transmission, specifically to a shielded connection interface adapter apparatus that facilitates electrical signal transmission from a signal input port to a signal output port at high signal fidelity.

### BACKGROUND OF THE DISCLOSURE

In the realm of electronic testing, one of the most challenging measurements to undertake is that of high bandwidth differential voltage amidst substantial common mode interference. This challenge is amplified when the interference encompasses high frequencies and voltages exceeding 40 volts. Modern measurement systems often provide exceptionally high common mode rejection ratio, significant common mode voltage rating, and extensive bandwidth. However, to fully leverage the performance capabilities of such systems, it is imperative that the test connections are of high quality and do not undermine the system's performance.

A common practice in electronic testing is to design test points into the device under testing (DUT). MMCX connectors, which are industry-standard connectors known for their bandwidth capabilities, are often utilized as test point interfaces on test and measurement probes, since they provide a shielded coaxial environment up to the test point and a high common mode rejection. MMCX connectors are not only effective in enhancing overall performance but are also readily available from online suppliers at a reasonable cost, making them an attractive option for test point creation.

However, the process of connecting the MMCX connector to the test point of the DUT, especially after the DUT has been built, poses several challenges. Installation of MMCX connectors on printed circuit boards (PCBs) to create high-quality test points requires a PCB that allows access to through-hole solder joints or requires a PCB with no through-hole vias. The process involves adapting surface mount and through-hole MMCX connectors to connect to gate and source nodes on different types of boards.

Another way of achieving a high-quality test point is utilizing existing interfaces on the board, such as square pin connection interfaces. Such existing interfaces can be accessed via an adapter, adapting them from said existing interface to MMCX.

Square pin-to-MMCX adapters are known, which are capable of adapting an MMCX Iso Vu tip to standard 0.100″ spaced, 0.025″ square pins. Such adapters typically have voluminous cylindrical body which makes it hard to access dedicated test points located in compact areas of the DUT. Other adapters offer the possibility to adapt a DL-ISO MMCX to high-voltage 0.1″ square pins, limiting it to a specific use case in the field of electronic testing and signal transmission.

However, adapting electrical signals from a signal input port to a signal output port often comes with substantial electromagnetic interference, hence signal deterioration. For example, a planned test point of a DUT may be a square pin socket, but an available measurement probe has an MMCX coaxial type input. Utilizing known MMCX to square pin type adapters often degrades the performance of the test system. It is often impossible for test and measurement probes to distinguish high bandwidth differential voltage measurements from high frequency interference by utilizing known MMCX to square pin type adapters mentioned above. As a result, the test system cannot measure the intended high-fidelity signal at the DUT test point.

To overcome the interference, engineers typically resort to implementing unplanned test points in their DUT. For example, an engineer may add a radio frequency (RF) PCB connector, such as an MMCX male straight surface mount, to the PCB as an unplanned test point and connect the available measurement probe to the unplanned test point to detect high-fidelity signals.

However, adding such unplanned test points has major industrial drawbacks. Adding additional hardware to the DUT is often not possible due to space constraints. Oftentimes, internal policies or project guidelines may prohibit such changes to the DUT for various quality control or regulatory reasons. In addition, modifying PCBs or DUTs is expensive and not optimal for reproducibility of test and measurement results.

There exists a need for an adapter that addresses these and other shortcomings by transmitting electrical signals from a signal input port to a signal output port with high signal fidelity. Specifically, adapter versatility is needed for compatibility with various output connectors and that provides both optimal electromagnetic interference (EMI) shielding and adaptability to coaxial connectors.

### SUMMARY OF THE DISCLOSURE

What is needed is a shielded connection interface adapter with stacked laminated portions that provides input and output versatility while shielding transmitted signals from common mode electromagnetic interference, such that a high signal fidelity is achieved for the signal transmitted through the shielded connection interface adapter.

A shielded connection interface adapter with stacked laminated portions is provided, suitable for use in electronic testing and signal transmission in high bandwidth differential voltage applications amidst substantial common mode interference.

The adapter has at least two laminated portions arranged in a stacked configuration with a bridge insert nested within the adapter interior. The stacked configuration and exterior wall, edge, and bumper structures of the two laminated portions shield the signal transmission input port and the signal transmission output port from external electromagnetic interference.

In one embodiment, the adapter portions may comprise a plurality of laminated plates laminated with copper, glass epoxy, black oxide, ceramic, Teflon, fire retardant composition, or ferrite. The adapter interior may contain an electromagnetic barrier that shields the signal output port and the signal input port from internal electromagnetic interference.

In a preferred embodiment, the adapter comprises a dual-end socket, having square pin socket ports on an input end and an MMCX socket port on an output end.

In one embodiment, the adapter has at least one signal transmission port such as a square pin socket input connected to a planned test point on a DUT and at least one signal transmission port such as a coaxial output connected to a coaxial probe tip of a test and measurement probe device while maintaining electromagnetic interference shielding.

### BRIEF DESCRIPTION OF THE DRAWINGS

The accompanying drawings that are incorporated in and constitute a part of this specification illustrate several embodiments of the disclosure. Together with the description, they serve to explain the principles of the disclosure.

FIG. 1 illustrates an exemplary adapter in an exploded view.

FIG. 2 illustrates an exemplary adapter in a top view.

FIG. 3A illustrates an exemplary adapter in a front view.

FIG. 3B illustrates an exemplary adapter in a rear view.

FIG. 4 illustrates an exemplary adapter in a perspective view.

FIG. 5 illustrates an exemplary adapter in an exploded view.

FIG. 6 illustrates an exemplary adapter in a rear view.

FIG. 7 illustrates an exemplary adapter with an output cable mounted to a signal output port in a top view.

FIG. 8 illustrates an exemplary adapter in a top view.

FIG. 9 illustrates an exemplary adapter used with a DUT and test and measurement probe.

### NUMERALS OF THE FIGS.

1. Connection interference adapter (“adapter”)
2. Adapter interior
3. First laminated portion (“first”)
4. Electromagnetic barrier
5. Second laminated portion (“second”)
7. Signal input port
9. Signal output port
11. Bridge insert
13. Bridge first end
15. Bridge second end
17. Bridge female input socket
19. Bridge female output socket
21. First top surface
23. First bottom surface
25. Second top surface
27. Second bottom surface
29. First left protrusion edge
31. First left protrusion edge front wall
33. First left protrusion edge interior wall
35. First left protrusion edge exterior wall
37. First right protrusion edge
39. First right protrusion edge front wall
41. First right protrusion edge interior wall
43. First right protrusion edge exterior wall
45. Second left protrusion edge
47. Second left protrusion edge front wall
49. Second left protrusion edge interior wall
51. Second left protrusion edge exterior wall
53. Second right protrusion edge
55. Second right protrusion edge front wall
57. Second right protrusion edge interior wall
59. Second right protrusion edge exterior wall
61. First center recessed port opening
63. Second center recessed port opening
65. First non-recessed opening
67. Second non-recessed opening
69. First left channel cutout
71. First right channel cutout
73. First channel wall
75. Second channel wall
77. Second left channel cutout
79. Second right channel cutout
81. First left bumper wall
83. First right bumper wall
85. First center bumper wall
87. Second left bumper wall
89. Second right bumper wall
91. Second center bumper wall
93. First signal transmission port
95. Second signal transmission port
97. Cable
99. Spring contact
101. Fixed contact
103. Test and measurement probe device
105. Probe tip cable
107. Male coaxial probe tip
109. Signal output port
111. Connection interface adapter (“adapter”)
113. Signal input port
115. DUT
117. Planned test point

### DETAILED DESCRIPTION

The present disclosure provides generally for shielded connection interface adapter apparatuses suitable for electronic testing and signal transmission in high bandwidth differential voltage applications amidst substantial common mode interference. The exemplary shielded connection interface adapter with stacked laminated portions (the “adapter”) generally has a dual-end socket constructed of a bridge insert nested within a first laminated portion and a second laminated portion arranged in a stacked configuration. The adapter also has two signal transmission ports, a signal output port, and a signal input port. The signal output port and the signal input port are connected to the bridge female output and input sockets, respectively, while housed within the stacked first laminated portion and second laminated portion.

The laminated portions can be constructed from PCBs or molded casings made of metal, glass, fiberglass, woven glass fiber, pre-preg composite, epoxy, resin, vinyl ester, cement, plastic, rubber, silicone, thermoplastic polymer, or other dielectric material.

Signal transmission ports of the disclosure can be combinations and include sub-combinations of the following: male-male, female-female, female-male, or male-female; input or output; and socket or pin. Signal transmission ports can have, comprise, or consist of input or output ports of various radio frequency connectors such as BNC, SMA, SMB, N, TNC, MCX, MMCX, or other known signal transmission ports or radio frequency connectors. The signal input port may be a radio frequency connector device, a pin, a socket, or a combination thereof. The signal output port may be a radio frequency connector device, a coaxial cable connector, or a coaxial cable.

The adapter laminated portions may be pre-preg composite or may be plates laminated with copper, glass epoxy, black oxide, ceramic, Teflon, or a fire-retardant composition, or combinations thereof. The plates may be stacked to form a single laminated portion. The adapter has an interior containing an electromagnetic barrier such as conductive metal filling or bridge enclosures made of ferrite, copper, brass, nickel, steel, or tin; electromagnetic interference shielded gaskets; conductive spray coating; or wire mesh; or combinations thereof.

One of the most needed shielded connection interfaces is one between an MMCX coaxial signal output port and a square pin signal input port. When a test and measurement probe that has its own unique electromagnetic shielding features is used on a DUT test point that has its own unique electromagnetic shielding features, the traditional wire-wire and ground-ground connections between the probe and DUT create excessive electromagnetic interference to where the probe cannot detect the high-fidelity voltage signal differential in power electronics applications. This is especially seen in applications where the probe is coaxial, but the DUT test points are square pin, and there has been a long-felt need in the test and measurement industry for a cost-effective, non-disruptive, and compact device that interfaces seamlessly with coaxial radio frequency connectors or cables, ensuring a stable and low-impedance connection. Exemplary embodiments are suitable for use in electronic testing and signal transmission in high bandwidth differential voltage applications amidst substantial common mode interference.

In some embodiments of disclosure, an adapter may contain additional active components such as circuitry. In some embodiments of the disclosure, an adapter may contain additional passive components such as resistors, inductances, or capacitors.

One specific preferred embodiment has a first end having a square pin socket as an input port and a second end having an MMCX socket as an output port. a top PCB layer, and a bottom PCB layer, wherein the dual end socket is embedded between the top and bottom PCB layers. The shielded adapter body is embedded fully or partially between the first and second PCB layers.

The disclosure presents exemplary embodiments of adapters having external lamination, internal electromagnetic barriers, stacked structure, channel cutouts, and port openings in a configuration that allows for a reduced footprint while maintaining effective electromagnetic interference shielding while measuring high-fidelity differential voltage signals on a DUT at the DUT's planned test points.

In the following sections, detailed descriptions of examples of the disclosure will be given. The description of both preferred and alternative examples is exemplary only, and it is understood that to those skilled in the art that variations, modifications, and alterations may be apparent. It is therefore to be understood that the examples do not limit the broadness of the aspects of the underlying disclosure as defined by the claims.

### Detailed Descriptions of the Drawings

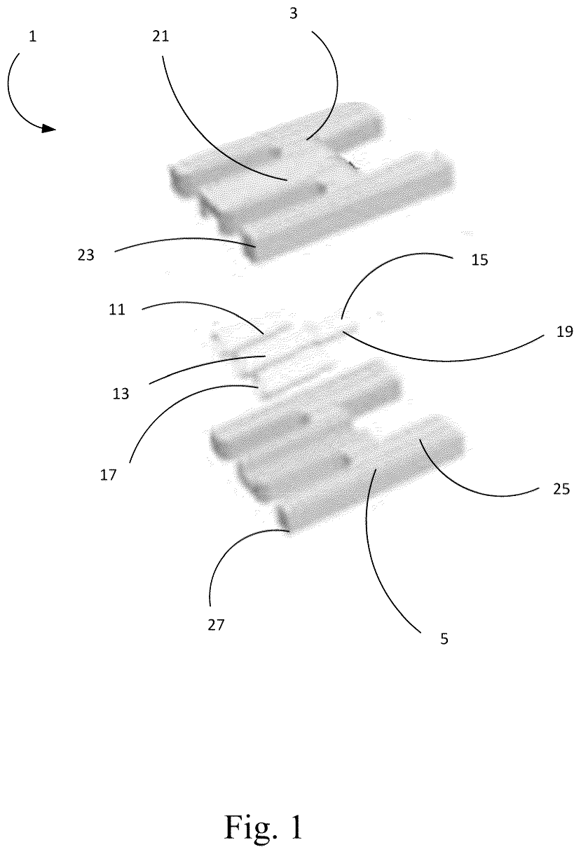

Referring to FIG. 1, an adapter in an exploded view is illustrated. The adapter has a dual-end socket configuration, and comprises two signal transmission ports, a signal input port and a signal output port. The dual-end socket configuration of the adapter integrates seamlessly to an external coaxial connector or cable, eliminating the need for additional components or adapters. The signal input and output ports may be arranged in line, parallel, or perpendicular to one another. A bridge insert has a first end and a second end with a female input socket and a female output socket, respectively.

In this embodiment, each square pin socket of the signal input port is equipped with a shielding mechanism to minimize electromagnetic interference. The first laminated portion and the second laminated portion are substantially identical mirror-image components and are configured to house a bridge insert in a stacked configuration. The stacked laminated portion configuration allows for a reduced footprint while maintaining effective electromagnetic interference shielding.

In this particular example, an MMCX socket port is connected to the middle square pin socket port in such a way that the MMCX socket port and the middle square pin socket port share the same longitudinal axis. The left and right square pin socket ports are connected to the middle square pin socket port such that they run in parallel and spaced apart from the middle square pin socket port.

The first and second portions each comprise a non-recessed opening and a recessed opening along their respective longitudinal axes for accommodating a middle square pin socket port and the MMCX socket port where the square pin socket port is a signal input port, and the MMCX socket port is a signal output port. The recessed and non-recessed openings may have a semi-circular cross-section and may or may not comprise beveled edges, gaskets, or stepped portions for additional abutment surfaces for enclosure and shielding of the bridge insert and signal input and output ports.

The first and second portions each comprise a left and right channel cutout and a channel wall that may be curved. The channel cutouts are configured to accommodate the left and right square pin ports of the signal input port. The first and second portions each have a non-recessed opening that encompasses the entirety of the center pin female input socket of the bridge insert, while the left and right square pin sockets of the bridge insert are not entirely enclosed by the first and second portions due to the right and left channel cutouts exposing the bridge insert while being partially enclosed by the first and second channel walls. Left, center, and right bumper walls enclose the signal input port (three square pins in this example), leaving a non-recessed opening (three, one for each square pin in this example).

The adapter accommodates a signal output port at the recessed opening. The recessed opening is between a first and second portion left protrusion edge and a first and second portion right protrusion edge. The left and right protrusion edges each have a front wall, an interior wall, and an exterior wall. The signal output port such as an MMCX coaxial port preferably frictionally fits or seamlessly fits between the left and right protrusion edges and against the left and right protrusion edge interior walls.

The square pin socket ports may have a standard pitch used for breadboards, e.g. 01 inches. Likewise, the pitch may be any other pitch used in the art, for example but not limited to 1.20 mm, 1.25 mm, 1.5 mm, 6 mm, 10 mm, 0.3 in, 0.4 in. The square pins may or may not be mounted to the side of a DUT. The square pin socket ports may be hot swap sockets, e.g. Mill-Max Hotswap sockets.

Furthermore, the adapter may or may not comprise a DC block, an input attenuator, and an input termination. In the context of the present disclosure, a DC block may be a coaxial component that prevents the flow of direct current frequencies while offering a minimum interference to RF signals. In the context of the present disclosure, an input attenuator may be any component suitable for reducing the amplitude level of an incoming signal. In the context of the present disclosure, an input terminator may be any component suitable for reducing the noise burden in the system.

The adapter incorporates shielded embedding of any input connectors, such as square pins, inserted into the sockets. The coaxial connector adaptation is achieved by configuring the embedded square pin sockets to align with and securely interfacing with the corresponding components of a coaxial connector. This direct integration ensures a reliable and low-impedance connection while providing optimal shielding from external interference.

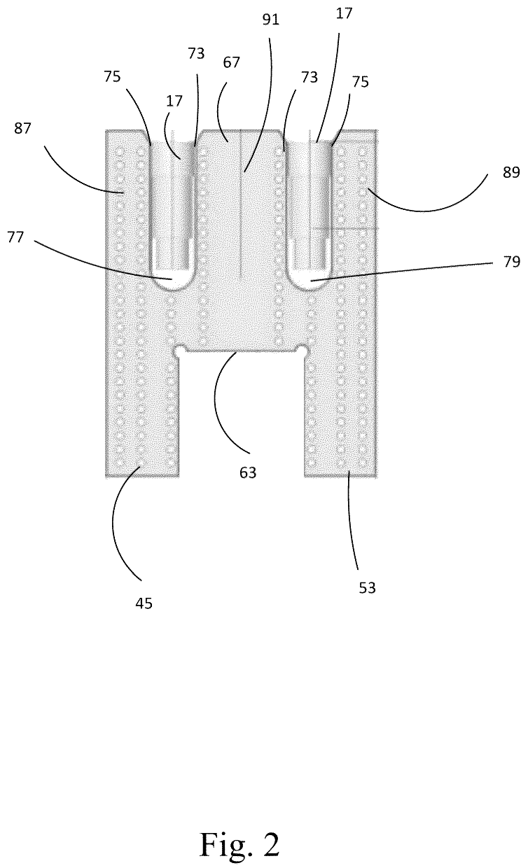

Referring now to FIG. 2, an adapter in a top view is illustrated. In the shown embodiment, the adapter may show the adapter of FIG. 1 in an assembled stacked configuration. The top PCB layer and the bottom PCB layers are stacked flush atop one another. The output cutout has a square cross-section for accommodating an MMCX socket via the output end of the adapter.

The two input cutouts each comprise a beveled edge on the input end. On their end opposite to the input end, the input cutouts comprise an ellipsoid abutment.

The left square pin socket port and the right square pin socket port are arranged flush inside the input cutouts and flush with the beveled edge of PCB layers. The top and bottom PCB boards comprise several rows of through-hole vias, running along the longitudinal length thereof.

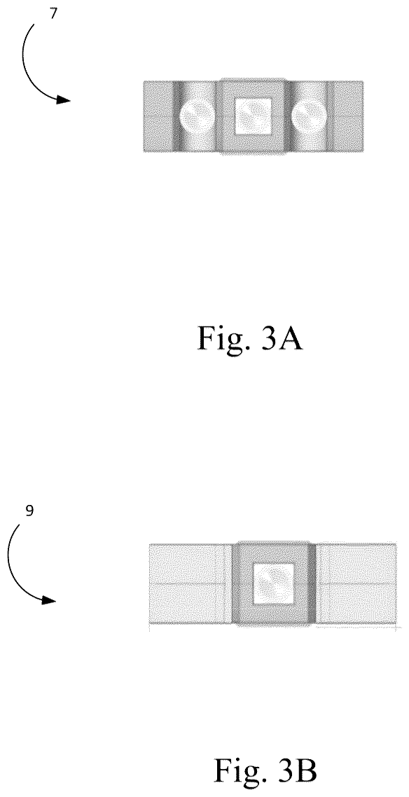

Referring now to FIG. 3A, an exemplary adapter in a front view is illustrated. In this embodiment, the signal input port has three pins, where the two end pins are embedded in the bridge insert input socket at the bridge first end and lie in the left and right channel cutouts of the first laminated portion and of the second laminated portion, surrounded by the left and right channel walls. A central pin is also embedded in the bridge insert input socket at the bridge first end where the first and second laminated portion non-recessed opening is located. The bridge input socket for the center pin is entirely embedded within the adapter interior.

Referring now to FIG. 3B, an exemplary adapter is illustrated in a rear view. In this embodiment, the signal output port is located at a center recessed port opening of the first and of the second laminated portion and is surrounded by the front wall, interior wall, and exterior wall of the first laminated portion left and right protrusion edges and the second laminated portion left and right protrusion edges and between the first laminated portion top surface and the second laminated portion top surface. The signal output port is connected to the bridge insert at the bridge second end having the bridge female output socket.

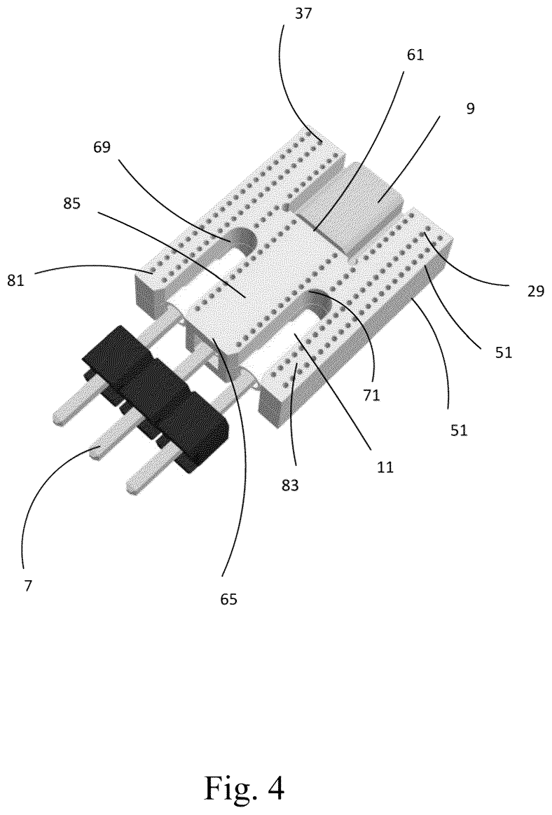

Referring now to FIG. 4, an exemplary adapter is shown in a perspective view. According to this specific embodiment, the adapter comprises a signal output port in the form of an MMCX socket mounted to the MMCX socket port of the dual-end adapter. The MMCX socket is arranged inside the output cutout and ends flush with the output end of the adapter. The adapter further comprises a square pin pack comprised of three square pins. The three square pins may be placed on a DUT (not shown) or soldered thereon. The MMCX socket may further be equipped with an adaptive structure that interfaces seamlessly with coaxial RF connectors or cables, ensuring a stable and low-impedance connection.

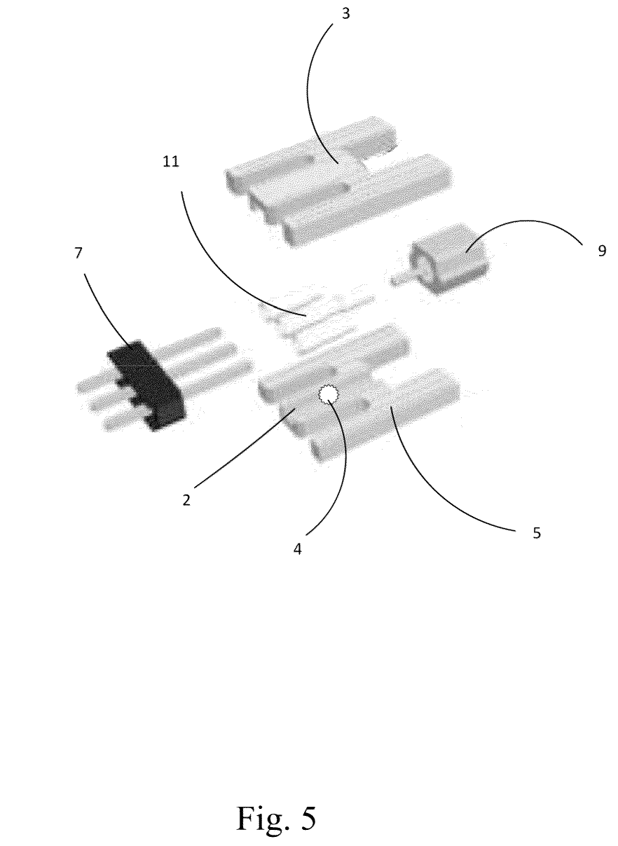

Referring now to FIG. 5, an exemplary adapter is shown in an exploded view. FIG. 5 shows an exemplary embodiment where the signal output port is an MMCX socket. The MMCX socket comprises an MMCX socket pin and may or may not have GND pins. In the shown embodiment, the MMCX socket is a standard MMCX jack (Female) PCB connector end with removed GND pins. In an assembled state, the MMCX socket pin is inserted into the MMCX socket port of the dual end socket. In an assembled state, the square pins of the square pin pack are inserted into the square pin ports of the signal input port.

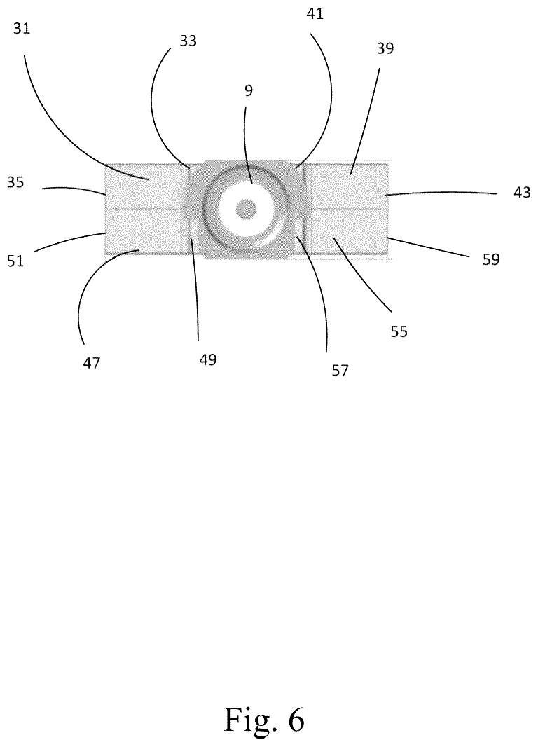

Referring now to FIG. 6, an exemplary adapter is shown in a rear view. In this specific exemplary embodiment, the signal output port is an MMCX socket which is inserted into the recessed opening of the adapter formed by the first laminated portion and the second laminated portion. The MMCX socket pin is nested substantially flush with the respective front walls of the first and second laminated portion protrusion edges.

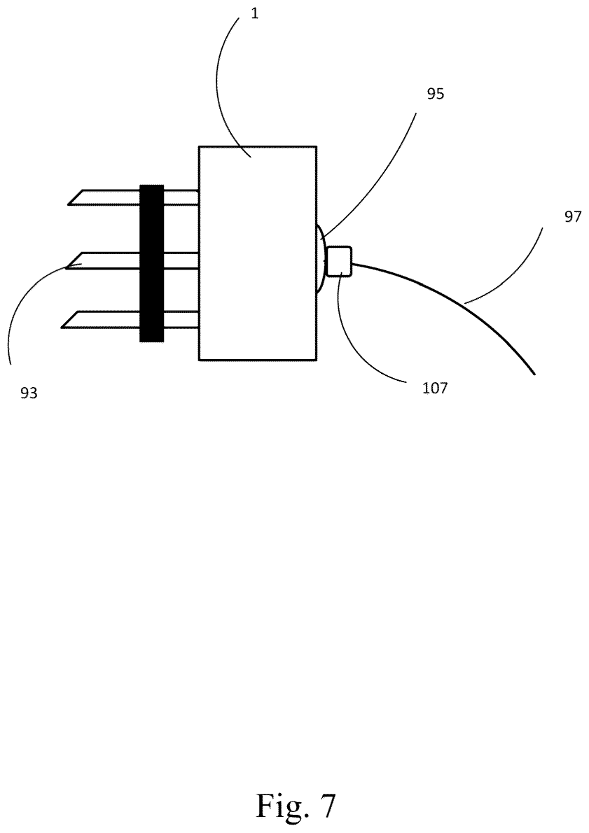

Referring now to FIG. 7, an exemplary adapter with an output cable mounted to the MMCX socket is shown in a top view. The adapter may contain laminated portions having an exterior lamination of rubber or plastic coating. An output cable is mounted to the MMCX socket of the adapter. The cable may be a coaxial radio frequency connector cable. The MMCX is further equipped with an adaptive structure that interfaces seamlessly with coaxial radio frequency connectors or cables, ensuring a stable and low-impedance connection. The direct integration of the signal input port and the signal output port to the bridge insert in a connection interface with a stacked configuration ensures a reliable and low-impedance connection while providing optimal shielding from external interference.

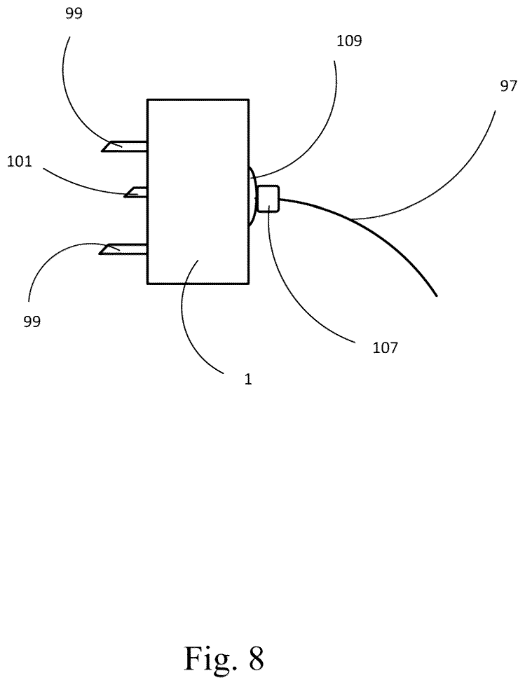

Referring now to FIG. 8, an exemplary adapter is shown in a top view. According to this embodiment, the adapter comprises three contact pins on its input end. The three contact pins have a 2.54 mm pitch. The outer two pins are spring contact pins. The center pin is a fixed contact pin. The outer two pins protrude further from the input end than the fixed contact pin. The signal output port is an MMCX socket which may or may not be soldered thereto. In some embodiments, it can be appreciated that a probe tip cable may be fixedly or removably attached to the signal output port.

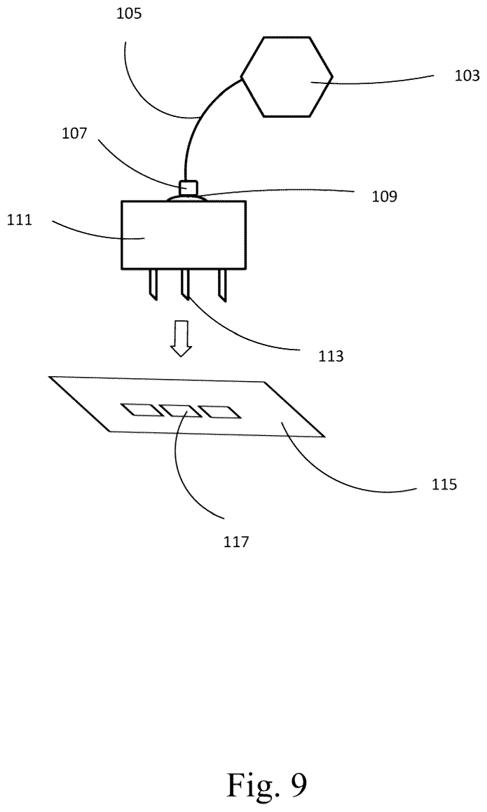

Referring now to FIG. 9, an exemplary adapter used with a DUT and test and measurement probe is shown. The DUT has a planned test point accommodating a square pin input port. The test and measurement probe device has a male coaxial probe tip that is not compatible with the square pin test point on the DUT. Therefore, the male coaxial probe tip is connected to the connection interface adapter at the signal output port. The adapter has a square pin signal input port that connects to the square pin test point on the DUT. The input port and the output port are shielded from electromagnetic interference providing a reliable and low-impedance connection while the probe detects differential high-fidelity voltage signals.

### Conclusion

A number of embodiments of the present disclosure have been described. While this specification contains many specific implementation details, these details should not be construed as limitations on the scope of any disclosures or of what may be claimed.

Certain features that are described in this specification in the context of separate embodiments can also be implemented in combination in a single embodiment. Conversely, various features that are described in the context of a single embodiment can also be implemented in combination in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Nevertheless, it will be understood that various modifications may be made without departing from the spirit and scope of the claimed disclosure.

What is claimed is:

1. An adapter, comprising:
a first laminated portion,
a second laminated portion,
a signal input port,
a signal output port,
a bridge insert,
wherein the first laminated portion and the second laminated portion are in a stacked configuration, and
wherein the adapter facilitates transmission of an electrical signal from the signal input port to the signal output port at high signal fidelity.

2. The adapter of claim 1, wherein the signal input port is a radio frequency connector device, a pin, a socket, or a combination thereof.

3. The adapter of claim 1, wherein the signal output port is a radio frequency connector device, a coaxial cable connector, or a coaxial cable.

4. The adapter of claim 1, wherein the bridge insert has a first end with a female input socket and a second end with a female output socket.

5. The adapter of claim 4, wherein the bridge female input socket and the bridge female output socket are longitudinally aligned to a non-recessed opening of the first and second laminated portion and to a recessed opening of the first and second laminated portion, respectively.

6. The adapter of claim 1, wherein the bridge insert is nested within a connection interface adapter interior.

7. The adapter of claim 1, further comprising an electromagnetic barrier within the connection interface adapter interior.

8. The adapter of claim 1, wherein the signal input port is electromagnetically shielded.

9. The adapter of claim 1, wherein the signal output port is electromagnetically shielded.

10. The adapter of claim 1, wherein the signal input port is a square pin port having three pins connected to the bridge insert female input socket, and the signal output port is a MMCX port connected to the bridge insert female output socket.
